(19) United States
(12) Patent Application Publication
(10) Pub. No.: US 2025/0185522 A1
(43) Pub. Date: Jun. 5, 2025

(54) ELECTRODE WITH SURFACE QUANTUM STATES AND APPLICATIONS THEREOF

(71) Applicant: Lakeside Lightning Semiconductor (Jiangsu) Co., Yixing City (CN)

(72) Inventors: Nan CHEN, Yixing City (CN); Zheng-Hong LU, Yixing City (CN); Chang-Sheng SHI, Yixing City (CN); Ning SUN, Yixing City (CN); Deng-Ke WANG, Yixing City (CN); Di WU, Yixing City (CN)

(21) Appl. No.: 18/789,828

(22) Filed: Jul. 31, 2024

(30) Foreign Application Priority Data
Dec. 1, 2023 (CN) 202311633461.8

(51) Int. Cl. H10N 60/85; H10K 10/82

(52) U.S. Cl. CPC H10N 60/851; H10K 10/82

(57) ABSTRACT

Provided is an anode with surface quantum states and a semiconductor device, which relates to the technical field of organic semiconductor optoelectronic devices. The anode with the surface quantum states is applied to a semiconductor device, including a substrate, a conductive anode, and a surface quantum state generation region arranged in sequence from bottom to top. Holes are directly injected into HOMO energy level of a hole transport layer through charge transfer quantum states on the surface of an anode, and thus the performance of the semiconductor device can be improved.

### CROSS-REFERENCE TO RELATED APPLICATION

This patent application claims the benefit of Chinese Patent Application No. 202311633461.8, filed on Dec. 1, 2023, the disclosure of which is incorporated by reference herein in its entirety.

### TECHNICAL FIELD

The present disclosure relates to the technical field of organic semiconductor optoelectronic devices, and in particular to an anode with surface quantum states and a semiconductor device.

### BACKGROUND

At present, various organic light-emitting diode (OLED) technologies have been actively developed. The OLED has been commercialized and occupied most share of the market in the neighborhood of white light illumination and flat panel display. Moreover, the next generation of OLED-based micro display will have important application and development advantages. For example, Apple Vision Pro AR/VR (Augmented reality/Virtual reality) head display and camera viewfinders introduced by Sony and Canon all use OLED micro display technology. Compared with the LED micro display, OLED micro display is more suitable for tiny high-resolution displays.

In order to achieve the commercialization of OLED micro display better, the optimization of the performance and structure of OLED is crucial at present. Because a silicon-based thin film transistor needs to be connected to one side of a substrate of a micro display product to drive the circuit, a top-emitting OLED with metal as a reflective anode at the bottom is needed. However, the silicon-based thin film transistor is difficult to provide high voltage, there is an urgent need for a technology capable of improving power efficiency while achieving high luminance at a low voltage. In addition, in order to achieve long standby time, further research is needed to achieve low power consumption.

Improving injection efficiency of the top-emitting device is to improve hole injection. There are two common methods for improving hole injection in industry: (1) a work function of the anode is changed by modifying an anode material, and the modified anode has a high work function, thus achieving the hole injection into the HOMO (highest occupied molecular orbital) level of the organic material, for example, chlorinating ITO (Indium Tin Oxide) (Ref. 1, 10.1126/science.1202992), and inserting a MoO₃ modification layer (ref.2, U.S. Ser. No. 10/818,865 B2). (2) A thick organic layer is inserted as a hole injection layer to form a step or an injection mode of a charge generation layer, thereby reducing the injection barrier of the hole, for example, evaporating CuPc (copper phthalocyanine) (ref.3, 10.1016/j.orgel.2003.10.001), PEDOT (2,3-Dihydrothieno[3,4-b][1,4]dioxine;(E)-2-phenylethenesulfonic acid) (ref.4, CN106025093A), HAT-CN (Dipyrazino[2,3-f:2′,3′-h]quinoxaline-2,3,6,7,10,11-hexacarbonitrile) (ref.5-10, CN116528649A, CN116425667A, CN115148940A, US201113082292A, CN103050631A, CN103280535A), F₄-TCNQ (2,3,5,6-Tetrafluoro-7,7′,8,8′-Tetracyanoquino-dimethane) (ref.11, CN1983664A), and the like, on ITO. Such a material, as the hole injection layer, has an optimized thickness usually in a range from 10 to several tens of nm, and cannot directly match the HOMO level of a luminescent host material.

In the top-emitting OLED device, aluminum is generally used as the reflective anode in industry, but the work function of the aluminum is only 4.2 eV, which is particularly low and makes the effective injection of holes difficult, affecting the turn-on voltage and efficiency of the device. Meanwhile, when applied to electroluminescent devices needing to display with different colors, different light-emitting layers need to match different hole transport layers and levels of host materials. It is often necessary to insert several layers of functional layer materials for buffering large hole injection barrier. For example, transition layers, such as NPB, TAPC and TCTA, are sandwiched between the injection layer and the deep-level CBP, which not only increases the complexity of the manufacturing process and the production cost, but also introduces more interfaces into the device, there are carrier accumulation at these interfaces even under high driving voltage, accelerating the molecular degradation at the interfaces and leading to the accelerated aging of the device.

### SUMMARY

An objective of the present disclosure is to provide an anode with surface quantum states and a semiconductor device. Holes are directly injected into HOMO level of a hole transport layer through charge transfer quantum states on the surface of an anode, thus improving the performance of the semiconductor device.

To achieve the objective above, the present disclosure provides the following solutions:

An anode with surface quantum states includes:
a substrate, a conductive anode, and a surface quantum state generation region, which are arranged in sequence from bottom to top.

Alternatively, the substrate is a silicon-based printed circuit board, or a substrate including thin film transistors.

Alternatively, the conductive anode includes metal, or a metal alloy.

Alternatively, the conductive anode includes aluminum.

Alternatively, the conductive anode includes one of copper, nickel, platinum, an aluminum-copper alloy, or an aluminum-titanium alloy.

Alternatively, the surface quantum state generation region includes metal, and an organic compound; and
the metal and organic compound in the surface quantum state generation region can undergo a charge transfer reaction.

Alternatively, the organic compound is an organic small molecular material with a lowest unoccupied molecular orbital level comparable to the work function of the metal.

Alternatively, the organic compound is HAT-CN (Dipyrazino[2,3-f:2′,3′-h]quinoxaline-2,3,6,7,10,11-hexacarbonitrile).

A semiconductor device includes:
an anode layer, a hole transport layer, an electroluminescent layer, an electron transport layer, an electron injection layer and a conductive cathode layer, which are arranged in sequence from top to bottom; and
the anode layer is the anode with surface quantum states.

Alternatively, the material of the hole transport layer is one of CBP (4, 4′-N, N′-dicarbazole-biphenyl), TCTA (4,4′,4″-tris(carbazol-9-yl)triphenylamine), TAPC (4,4′-cyclohexylidenebis[N,N-bis(p-tolyl)aniline]), NPB (N, N′-diphenyl-N, N′-bis(1-naphthyl-phenyl)-1, 1′-biphenyl-4, 4′-diamine), or m-MTDATA (4,4′,4″-Tris(N-3-methylphenyl-N-phenylamino)triphenylamine).

Alternatively, the material of the electroluminescent layer is one of Ir(ppy)₂(acac) (Bis(2-phenylpyridinato-C2,N) (acetylacetonate) iridium (III)), Ir(MDQ)₂(acac) (Bis(2-methyldibenzo[f,h]quinoxaline) (acetylacetonate) iridium (III)), Firpic (Bis[2-(4, 6-difluorophenyl)pyridinato-C2,N](picolinato) iridium (III)), quantum dots, or perovskite.

Alternatively, the conductive cathode layer includes a magnesium-silver alloy.

According to specific embodiments of the present disclosure, the present disclosure has the following technical effects:

According to an anode structure with surface quantum states, quantization in the surface is formed by a chemical reaction between a conductive anode and an organic compound. A quantization in the surface is generated by the following steps: step one, blending the conductive anode and a deep-level organic small-molecular material on the conductive anode; and step two, undergoing chemical reaction between the surface of the conductive anode and adsorbed organic molecules thereon. A charge transfer chemical reaction between the metal and the organic molecules leads to the formation of a metal-organic compound, thus inducing the quantum states in the surface. The characteristics of such a quantized electrode is that the holes are directly injected into the HOMO level of a hole transport layer through charge transfer quantum states on the surface of the anode, thus achieving an OLED device with high performance.

### BRIEF DESCRIPTION OF THE DRAWINGS

To describe the technical solutions of the embodiments of the present disclosure or in the prior art more clearly, the following briefly introduces the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a structural schematic diagram of an anode with surface quantum states according to Embodiment 1 of the present disclosure;

FIG. 2 is a structural schematic diagram of a semiconductor light-emitting device according to Embodiment 2 of the present disclosure;

FIG. 3 is a schematic diagram of the spectrum near Fermi level of UPS (ultraviolet photoelectron spectroscopy) based on a quantized anode and a non-quantized anode according to Embodiment 3 of the present disclosure;

FIG. 4 is a schematic spectrogram of N 1s core-level of XPS (X-ray photoelectron spectroscopy) based on a quantized anode and a non-quantized anode according to Embodiment 3 of the present disclosure;

FIG. 5 is a variable-temperature I-V characteristic curve graph of a single-carrier device based on a quantized anode according to Embodiment 3 of the present disclosure;

FIG. 6 is a schematic diagram of surface quantum states of a quantized anode and HOMO level of a hole transport layer (CBP) according to Embodiment 3 of the present disclosure;

FIG. 7 is a J-V-L curve graph of a top-emitting organic semiconductor device based on an anode with and without a quantum state generation region according to Embodiment 3 of the present disclosure;

FIG. 8 is an efficiency curve of a top-emitting organic semiconductor device based on an anode with and without a quantum state generation region according to Embodiment 3 of the present disclosure;

FIG. 9 is a spectrogram near a Fermi edge of UPS of a surface of a quantized anode according to Embodiment 4 of the present disclosure;

FIG. 10 is a spectrogram of N 1s core-level of XPS of a surface of a quantized anode according to Embodiment 4 of the present disclosure;

FIG. 11 is a performance diagram of a top-emitting organic semiconductor device based on a quantized anode according to Embodiment 4 of the present disclosure;

FIG. 12 is a UPS spectrogram of an anode without quantum state generation interface according to Embodiment 5 of the present disclosure;

FIG. 13 is an XPS N 1s spectrogram of an anode without quantum state generation interface according to Embodiment 5 of the present disclosure;

FIG. 14 is a J-V-L curve graph of a top-emitting OLED device based on an anode without a quantum state generation region according to Embodiment 5 of the present disclosure;

FIG. 15 is an efficiency curve of a top-emitting OLED device based on an anode without a quantum state generation region according to Embodiment 5 of the present disclosure.

In the drawings: 100, anode layer; 110, hole transport layer; 120, electroluminescent layer; 130, electron transport layer; 140, electron injection layer; 150, conductive cathode layer; 160, encapsulation layer; 101, substrate; 102, quantum state generation region.

### DETAILED DESCRIPTION OF THE EMBODIMENTS

The following clearly and completely describes the technical solutions in the embodiments of the present disclosure with reference to the accompanying drawings in the embodiments of the present disclosure. Apparently, the described embodiments are merely a part rather than all of the embodiments of the present disclosure. All other embodiments obtained by a person of ordinary skill in the art based on the embodiments of the present disclosure without creative efforts shall fall within the protection scope of the present disclosure.

An objective of the present disclosure is to provide an anode with surface quantum states, as well as a semiconductor device. Holes are directly injected into HOMO level of a hole transport layer through charge transfer quantum states on the surface of an anode, thus improving the performance of the semiconductor device.

In order to make the objectives, features and advantages of the present disclosure more clearly, the present disclosure is further described in detail below with reference to the embodiments.

### Embodiment 1

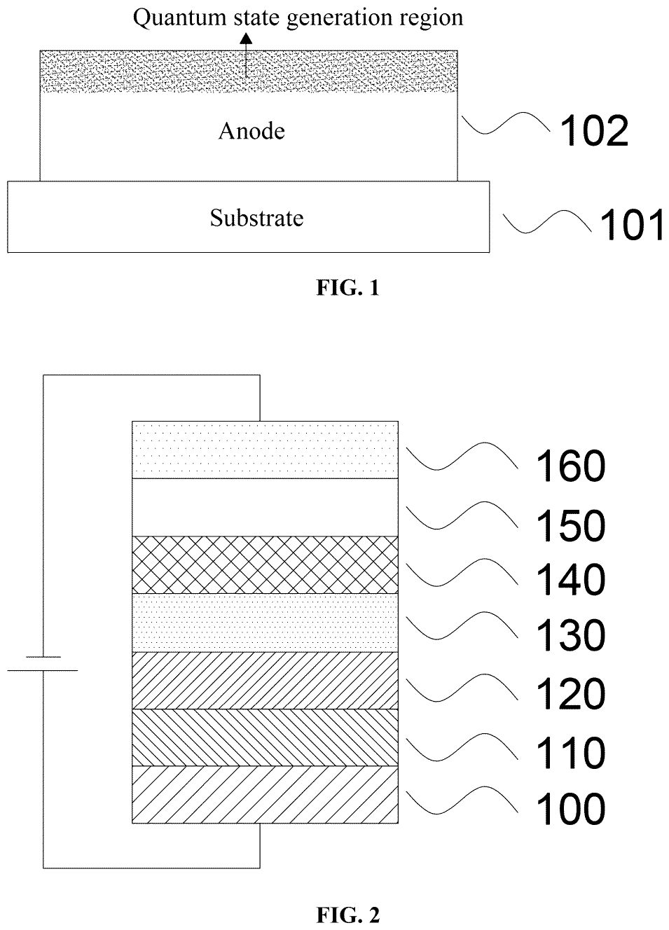

As shown in FIG. 1, an anode 100 with surface quantum states is provided in this embodiment, including a substrate 101, a conductive anode, and a surface quantum state generation region 102, which are arranged in sequence from bottom to top. The substrate is a silicon-based printed circuit board or a substrate including thin film transistors. The conductive anode includes metal or a metal alloy. The conductive anode has light reflectivity. The conductive anode includes one of aluminum (Al), copper (Cu), nickel (Ni), platinum (Pt), an aluminum-copper alloy, or an aluminum-titanium alloy. The surface quantum state generation region at the top of the conductive anode is formed by a chemical reaction between the surface and an organic compound. The surface quantum state generation region at the top of the conductive anode is a surface coating containing the metal and the organic compound. A semiconductor device with excellent high performance and high stability is prepared from the anode with the surface quantum state generation region. The surface quantum state generation region includes the metal and an organic compound. The metal and the organic compound in the surface quantum state generation region can undergo a charge transfer reaction. The organic compound is an organic small-molecular material with a lowest unoccupied molecular orbital (LUMO) level comparable to the work function of the metal, including HAT-CN, F₄-TCNQ, TCNQ, C₆₀, etc. The anode may be applied to an optoelectronic semiconductor device, including, but not limited to, an organic light-emitting diode, an organic solar cell, an organic field effect transistor, and other devices.

### Embodiment 2

A semiconductor device is provided by this embodiment, including an anode layer 100, a hole transport layer 110, an electroluminescent layer 120, an electron transport layer 130, an electron injection layer 140 and a conductive cathode layer 150, which are arranged in sequence from top to bottom. The anode layer is the anode with surface quantum states of Embodiment 1.

The material of the hole transport layer is one of CBP, TCTA, TAPC, NPB, or m-MTDATA. The material of the electroluminescent layer is one of Ir(ppy)₂(acac), Ir(MDQ)₂(acac), Firpic, quantum dots, or perovskite. The electroluminescent layer is located between a reflective anode and a conductive and optical-transparent cathode layer. The cathode is conductive and transparent. The conductive cathode layer includes a magnesium-silver alloy. The anode layer is connected to a silicon-based printed circuit board or a thin film transistor based on a glass substrate to provide a positive electrode, and the cathode layer provides a negative electrode. Alternatively, the anode layer is connected to a positive electrode of a power supply, and the cathode layer is connected to a negative electrode of the power supply.

The optoelectronic device (semiconductor device) can be made into a flexible light-emitting device. Preferably, the substrate is a transparent flexible material, which is one of a cyclic olefin polymer (COP), a liquid crystal polymer (LCP), polycarbonate (PC), polydimethylsiloxane (PDMS), polyethylene (PE), polypropylene (PP), polyethylene naphthalate (PEN), polyethersulfone resin (PES), polyethylene terephthalate (PET), polyimide (PI). The substrate of the light-emitting diode includes, but not limited to, a glass substrate, and the application on an OLED, a photoelectric detector, a photoelectric sensor, a solar cell, a tunneling diode, and a solid-state laser. The substrate of the light-emitting diode is a silicon substrate containing an OLED driving circuit. The light-emitting diode is a top-emitting light-emitting diode device, the anode in contact with the substrate is an opaque conductive anode, and the cathode is a transparent conductive anode. The electroluminescent unit on the anode is one layer or multiple layers of organic luminescent materials, which may be a perovskite luminescent material, or a quantum dot luminescent material. The light-emitting device may also include an electron transport layer on the electroluminescent material layer. The cathode may be a conductive and optical-transparent laminated structure, or a mixed structure. The device further includes an encapsulation layer 160 arranged above the transparent cathode. The optoelectronic device with a molecular anode provided in this embodiment includes, but is not limited to, a light-emitting diode, an organic light-emitting diode, a solar cell, an organic solar cell, a field effect transistor, an organic field effect transistor, and other devices.

This embodiment is specifically described below with a top-emitting structure as an example.

As shown in FIG. 2, a top-emitting structure includes an anode (layer) 100, a hole transport layer 110, an electroluminescent layer 120, an electron transport layer 130, an electron injection layer 140 and a metal cathode (conductive cathode layer) 150, which are laminated in sequence. The anode 100 includes a substrate 101, a conductive anode, and a quantum state generation region 102 at the top of the conductive anode.

The substrate 100 includes, but not limited to, a glass substrate, an OLED, a photodetector, a photoelectric sensor, a solar cell, a tunneling diode, and a solid-state laser. The surface quantum state generation region at the top of the conductive anode in the anode 110 is formed by the chemical reaction between the surface and an organic compound. The conductive anode in the anode 100 includes one of aluminum (Al), copper (Cu), nickel (Ni), platinum (Pt), an aluminum-copper alloy, and an aluminum-titanium alloy, which is evaporated on the substrate by high vacuum deposition technology. The organic compound layer of the quantum state generation region of the anode 100 is formed by thermal evaporation, deposition and growth, and may include, but not limited to, HAT-CN, F₄-TCNQ, TCNQ, or C₆₀.

The hole transport layer 110 may be an organic-based material, which may be, but not limited to, CBP, NPB, TCTA, TAPC, m-MTDATA, etc., or may be any other layer or layers of organic small-molecular or polymer materials capable of transporting holes, with a thickness ranging from 1 nm to 500 nm.

The light-emitting layer 120 may be formed by co-depositing a host and a dopant, and has a thickness up to 15 nm. The light-emitting layer may also be a layer of organic compound capable of emitting different colors, and has a thickness ranging from 10 nm to 100 nm. The luminescent material may be, but limited to Ir(ppy)₂, Ir(MDQ)₂(acac), or Firpic.

The electron transport layer 130 may include, but not limited to, TPBi, TmPyPB or Bphen, and other materials, and has an optimal thickness ranging from 40 nm to 70 nm.

The electron injection layer 140 in contact with the electron transport layer preferably includes LiF or Liq with a thickness ranging from 1 nm to 3 nm, preferably 1 nm, and the electron injection layer may be any fluoride, as long as the electronic layer is in direct contact with the electron transport layer.

The cathode structure 150 may be made of one layer or multiple layers of conductive metal and/or alloys, such as aluminum, chromium, copper, silver, gold, nickel, iron, tungsten, molybdenum, cobalt, a magnesium-silver alloy, and a lithium-aluminum alloy.

A preparation method for the device is as follows: all materials (including an organic material, a metal material and an oxide material) involved in the embodiment of the present disclosure are thermally evaporated in the same vacuum chamber to prepare the device, and the vacuum degree of the vacuum chamber is better than 5×10⁻⁵ Pa. An aluminum film is deposited in a PBN (pyrolytic boron nitride) crucible at a rate of 6.0 Å/s, and a thickness of the thin film is estimated by a calibrated quartz crystal monitor. The deep-level organic small-molecular material is thermally evaporated at a rate of 1.0 Å/s in the same evaporation chamber, under the similar pressure. A chemical state and an electronic structure of a sample are studied by X-ray photoelectron spectroscopy (XPS) and ultraviolet photoelectron spectroscopy (UPS). The XPS and UPS tests are carried out in a Thermofisher ESCALAB X+ system provided with a monochromatic Al Ka source, He I light source and a hemispherical electron analyzer. The top-emitting OLED device is prepared on the glass substrate by using a high-vacuum deposition system produced in Sky Technology Development Co., Ltd. Chinese Academy of Sciences. In the process of cleaning the substrate, acetone, methanol and deionized water each are used for ultrasonic cleaning, and finally, an ultraviolet ozone instrument is used for ultraviolet ozone treatment for 15 minutes.

### Embodiment 3

A new quantized anode provided in this embodiment has surface quantum states generated by the chemical reaction between metal Al and HAT-CN adsorbed on the surface, and can be preferentially used in a top-emitting organic light-emitting diode. A structure of the device includes a quantized anode/a hole transport layer/a light-emitting layer/an electron transport layer/an electron injection layer/a transparent cathode/an organic coupling layer.

Tests and characterization of surface quantum states of an anode are as follows:

Referring to FIG. 1 to FIG. 2, an anode in this embodiment includes metal Al in contact with a substrate, and a surface quantum state generation region generated by a chemical reaction between the metal Al and the HAT-CN adsorbed on the surface. The HAT-CN may be produced by a gas phase method, and a thickness of absorbed molecules on the surface is no more than 5 nm.

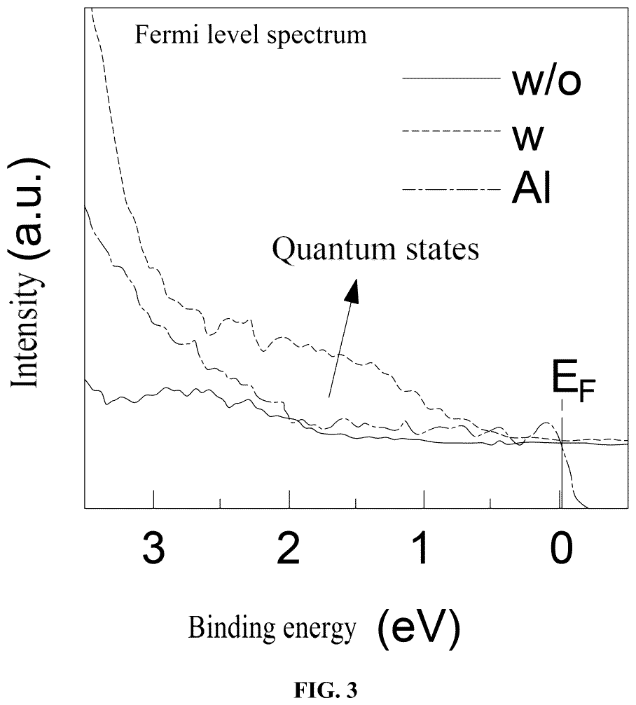

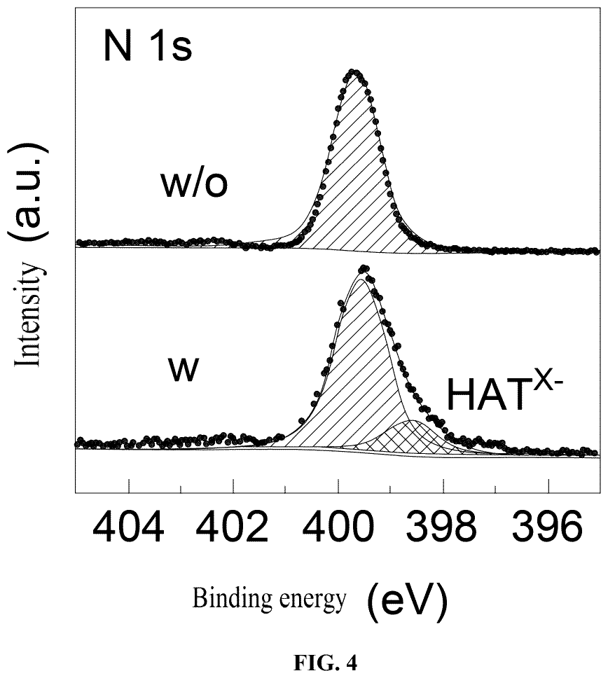

XPS and UPS spectrograms of the surface quantum state generation region in the anode structure are shown in FIG. 3 and FIG. 4. As shown in FIG. 3, the distribution characteristics of electronic states near the Fermi level are obtained by amplifying UPS valence band spectrum. The Fermi edge of pure Al crosses the Fermi level (a solid line labeled by Al). When the HAT-CN is adsorbed on Al to form the metal-organic compound, there are characteristics of electronic states in the UPS spectrum (a solid line labeled by icon w, indicating that the quantum states are generated). When the absorbed HAT-CN is too thick (>5 nm) (a solid line labeled by w/o, indicating that no quantum state is generated), there is no characteristic of electronic state in the UPS spectrum. The cause of quantum states is determined by the chemical shift of the N 1s core-level of the XPS, which is shown in FIG. 4. When the chemical absorption of the HAT-CN is less than 5 nm, a new N 1s peak (HAT^{x-}) appears when the Al and the HAT-CN undergo a charge transfer. Therefore, the Al and HAT-CN form a metal-organic compound, with a charge transfer therebetween, to generate charge transfer quantum states, and thus forming a quantized electrode.

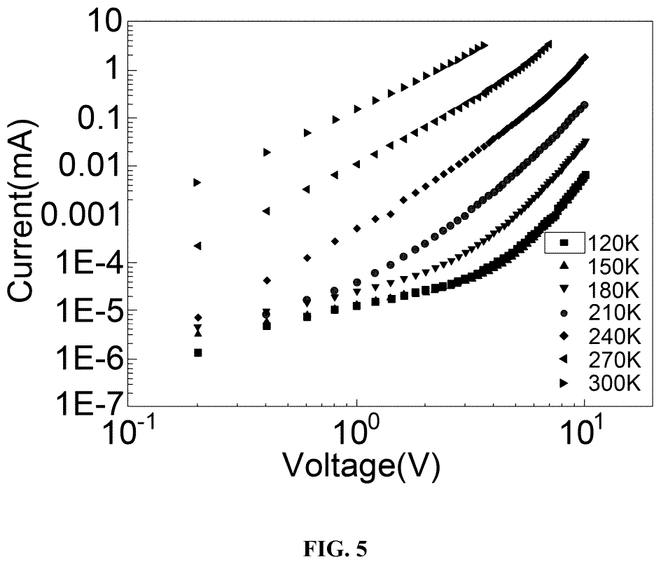

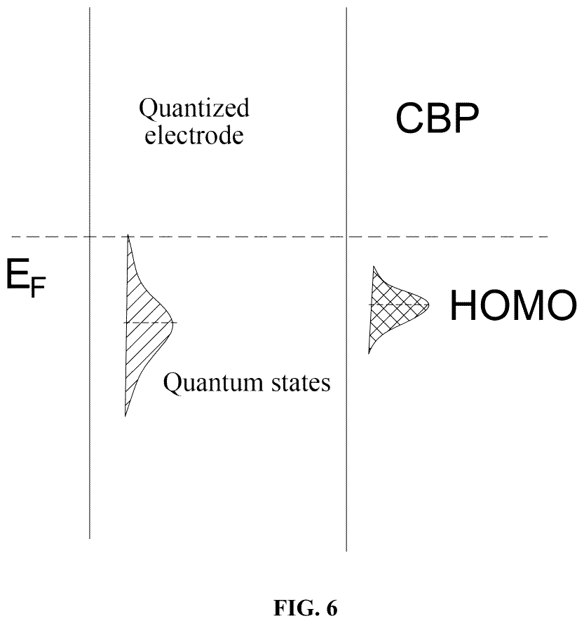

According to FIG. 5, it is found that a variable-temperature I-V curve of a single-carrier device (quantized anode/CBP 50 nm/HAT-CN 5 nm/Al 100 nm) based on a quantized anode is different from that of the traditional anode and has no obvious temperature dependence. That is, an injection mechanism of the anode in this embodiment is different from that of the traditional anode, and is closer to a molecular-molecular thermal activation jumping injection mechanism (ref.12-13, 10.1103/physrevb.75; 10.1063/1.3424762). That is, the distribution of the surface states of a quantum electrode is more similar to the HOMO distribution of molecules, as shown in FIG. 3. FIG. 6 is a schematic diagram of surface quantum states of a quantized electrode and HOMO level of a hole transport layer. It can be found that the holes are directly injected into the HOMO level of a light-emitting layer host through the quantum states in a surface.

The application of an OLED device based on the quantized electrode is as follows:

A structure of a top-emitting OLED device designed according to the present disclosure is as follows. A layer of metal aluminum (Al) is deposited on the glass substrate, with a preferable thickness of 100-200 mm. The surface-absorbed HAT-CT is prepared by the gas phase method, with a thickness less than 5 nm, and chemically reacts with the metal to form the quantum states in a surface, so as to form a quantized electrode. A hole transport layer CBP in contact with the quantized electrode has a thickness of 40 nm. The CBP is used as a host and Ir(ppy)₂(acac) is used as a phosphorescent guest (a doping ratio of the guest is 8 wt % and the thickness of the guest is 15 nm) to form the light-emitting layer. TPBi is used as an electron transport layer, with a thickness of 45 nm. Liq is used as the electron injection layer, with a thickness of 1 nm. The used cathode is a laminate electrode, Mg: Ag (3 nm)/Ag (20 nm)/NPB (75 nm).

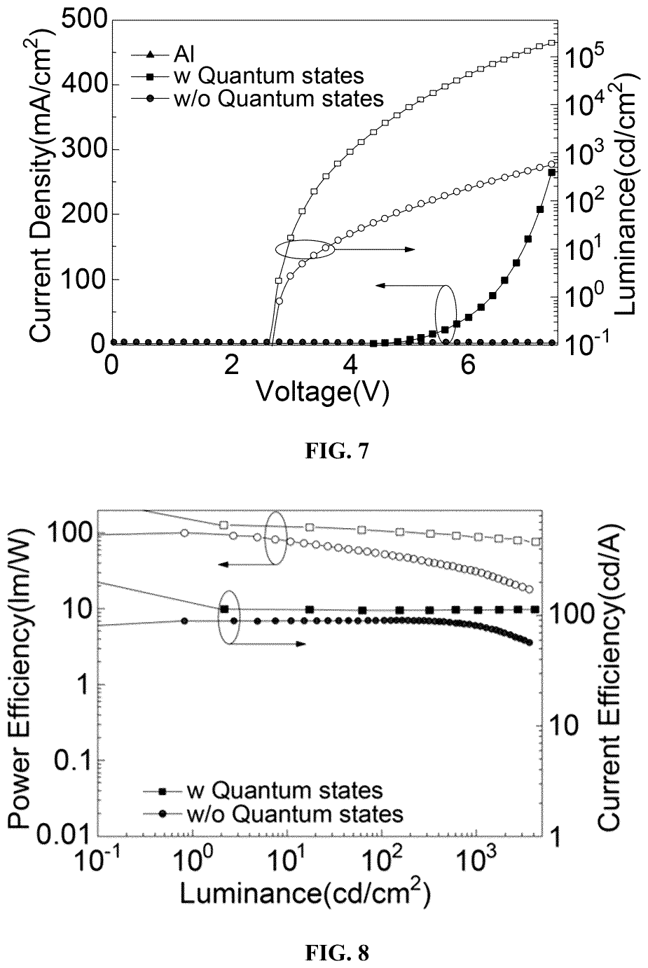

FIG. 7 shows a current density-luminance-voltage-(J-L-V) curve of a top-emitting OLED device when a quantized electrode and an anode with quantum states are used. The abscissa is voltage, the (left) ordinate is current density, and the (right) ordinate is luminance. FIG. 8 is a curve showing current efficiency and power efficiency of a top-emitting device. The abscissa is luminance, the (left) ordinate is the power efficiency, and the (right) ordinate is the current efficiency. It can be found that the performance of the top-emitting OLED device based on an anode with a quantum state region can be greatly improved. First of all, the top-emitting OLED device based on the traditional anode (i.e., only with Al metal, without quantum states) does not emit light and does not work. Under the high luminance of 2000 cd/m², a driving voltage of the top-emitting OLED device based on the quantized electrode (i.e., when HAT-CN less than 5 nm is adsorbed on Al to form the metal-organic compound) is within 4.26 V, while a driving voltage of the top-emitting OLED based on an anode without quantum state generation (HAT-CN greater than 5 nm is adsorbed on Al) is within 9.26 V. When the luminance is 2000 cd/m², the power efficiency and the current efficiency of a light-emitting device with the quantized electrode are 831 m/W and 112 cd/A, respectively. The power efficiency and the current efficiency of the device based on the anode without quantum state generation are respectively 221 m/W and 68 cd/A at the high luminance of 2000 cd/m². By comparison, it is shown that the device based on the quantized anode has higher current efficiency and power efficiency at high luminance, and the effectiveness of hole injection based on quantum states in a surface of the anode is confirmed. Meanwhile, it can be found that the device based on the quantized anode has stronger stability than the device based on the traditional anode.

### Embodiment 4

An anode provided in this embodiment has surface quantum states generated based on a chemical reaction between metal Al and surface-absorbed F₄-TCNQ, and can be preferentially used in a top-emitting organic light-emitting diode. A structure of the device includes a quantized anode/a hole transport layer/a light-emitting layer/an electron transport layer/an electron injection layer/a transparent cathode/an organic coupling layer.

Tests and characterization of the quantum states in a surface of the anode are as follows:

Referring to FIG. 1 to FIG. 2, the anode in this embodiment includes metal Al in contact with a substrate, and a surface quantum state generation region generated by the chemical reaction between the metal Al and the surface-absorbed F₄-TCNQ. F₄-TCNQ can be generated by a gas phase method.

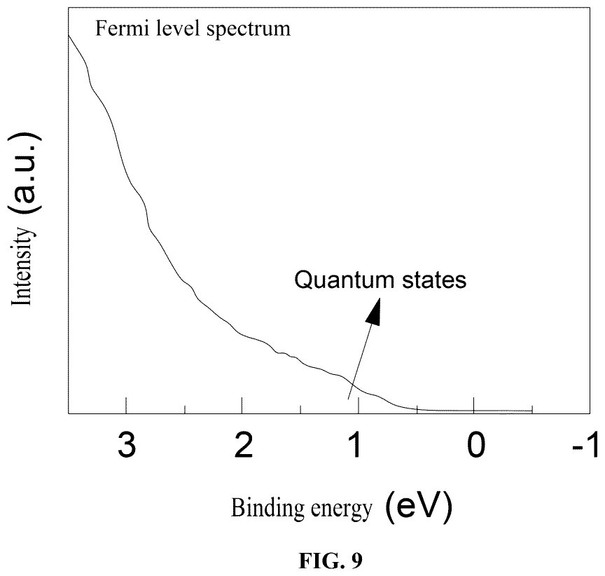

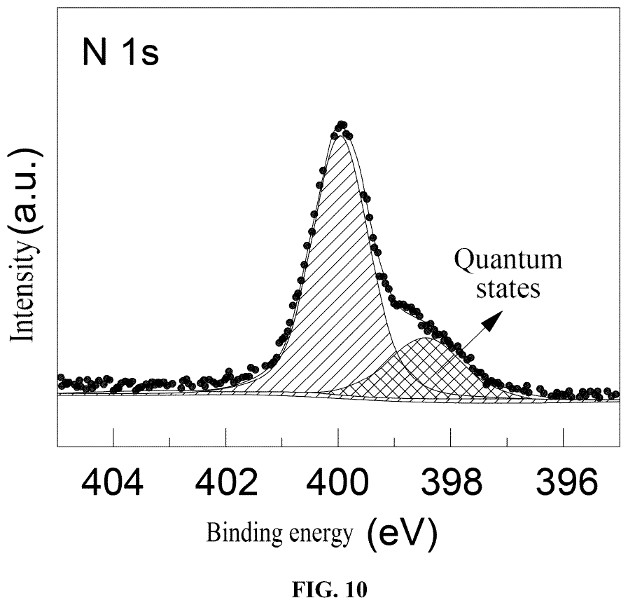

As shown in FIG. 9, the distribution characteristics of electronic states near the Fermi level are obtained by amplifying UPS valence band spectrum. When the F₄-TCNQ is absorbed on the Al to form a metal-organic compound, there are characteristics of electronic states in the UPS spectrum (denoted by font quantum states). As shown in FIG. 10, the XPS N 1s peak also has a new N 1s peak (a position with low binding energy indicates quantum states, which is denoted by the font quantum states), which is a charge transfer between Al and F₄-TCNQ to form a metal-organic compound, thus forming a quantum state generation region formed at the top of a conductive material to form the quantized electrode.

The application of the OLED device based on the quantized electrode is as follows:

A structure of a top-emitting OLED device designed in this embodiment is as follows. A layer of metal aluminum (Al) is deposited on a glass substrate, with a preferable thickness ranging from 100 nm to 200 nm. The surface-absorbed F₄-TCNQ prepared by a gas phase method chemically reacts with the metal to form surface quantum states, so as to form a quantized electrode. A hole transport layer CBP in contact with the quantized electrode has a thickness of 40 nm. The CBP is used as a host and Ir(ppy)₂(acac) is used as a phosphorescent guest (a doping ratio of the guest is 8 wt % and the thickness of the guest is 15 nm) to form the light-emitting layer. TPBi is used as an electron transport layer, with a thickness of 45 nm. Liq is used as the electron injection layer, with a thickness of 1 nm. The used cathode is a laminate electrode, Mg: Ag (3 nm)/Ag (20 nm)/NPB (75 nm).

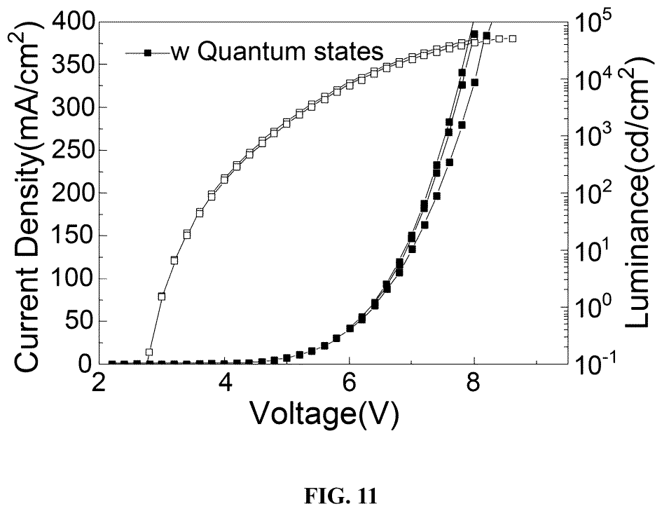

FIG. 11 shows a current density-luminance-voltage (J-L-V) curve of a top-emitting OLED device when a quantized electrode is used. The abscissa is voltage, the (left) ordinate is current density, and the (right) ordinate is luminance. It can be found that for the anode with a quantum state generation region formed based on Al and F₄-TCNQ, the performance of the top-emitting OLED device is excellent, and a turn-on voltage is within 2.8 V. Under the high luminance of 2000 cd/m², a driving voltage of the top-emitting OLED device based on the quantized electrode (i.e., F₄-TCNQ is adsorbed on Al to form a metal-organic compound) is within 5 V, indicating that the device based on the quantized anode has excellent device performance at high luminance. In this embodiment, the effectiveness of hole injection based on the quantized anode and the high performance of the quantized anode in the top-emitting device are confirmed.

### Embodiment 5

In order to confirm the effectiveness of the quantized anodes formed based on the metal Al and surface-absorbed HAT-CN in Embodiment 2 and Embodiment 3 of the present disclosure, an anode formed without quantum states based on ITO and surface-absorbed HAT-CN is designed in this embodiment. In a top-emitting organic light-emitting diode, a structure of the device includes an anode/a hole transport layer/a light-emitting layer/an electron transport layer/an electron injection layer/a transparent cathode/an organic coupling layer.

Tests and characterizations of the ITO/HAT-CN anode are as follows:

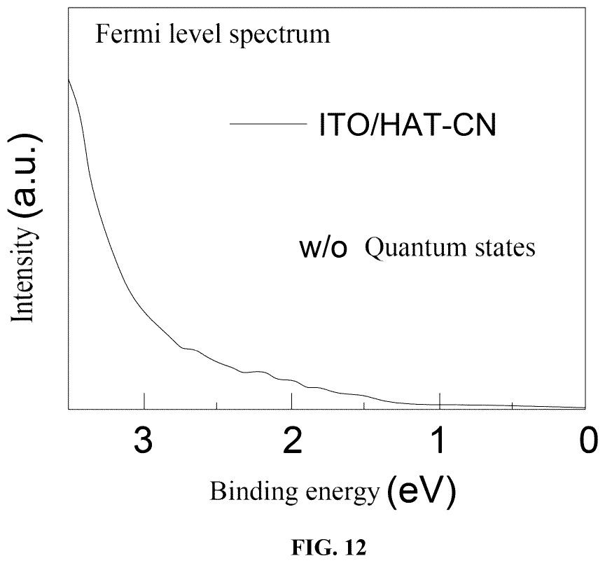

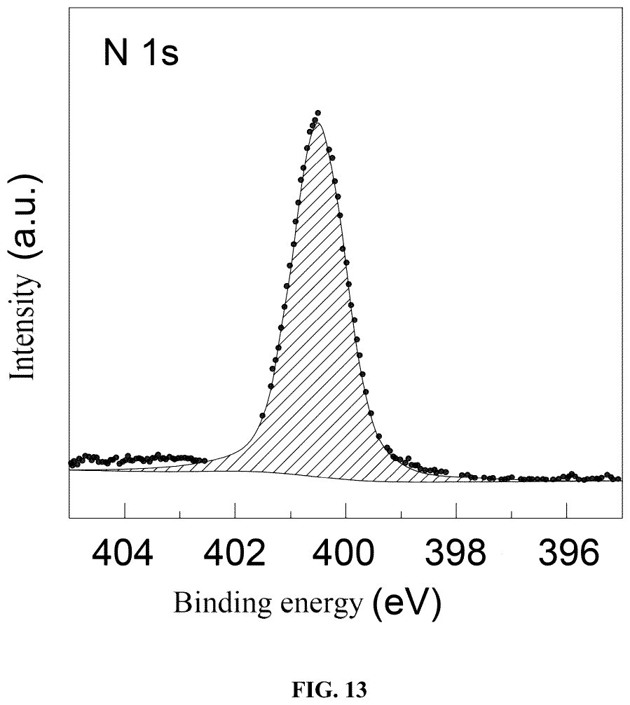

An anode based on an ITO/HAT-CN interface is prepared in this embodiment. The USP spectrogram of the ITO and HAT-CN interface and the N 1s core-level spectrogram of XPS are as shown in FIG. 12 and FIG. 13. As shown in FIG. 3, through amplifying the UPS valence band spectrum, it can be found that there is no electronic state information near the Fermi level of the ITO/HAT-CN interface (w/o indicates that no quantum state is generated). Combined with N 1s peak of XPS, there is only an intrinsic single peak of HAT-CN, and there is no charge transfer state, providing that there is no charge transfer on the ITO/HAT-CN interface and no quantum state in a surface generated on the metal surface. Therefore, no compound is generated between the ITO and the HAT-CN, no charge transfer occurs, and thus no quantized electrode is generated.

The application of an OLED device based on an ITO/HAT-CN anode is as follows:

A structure of a top-emitting OLED device designed according to the present disclosure is as follows. A layer of ITO and a HAT-CN interface of an organic small-molecular thin material are deposited on the glass substrate to form an anode. A hole transport layer CBP in contact with the anode has a thickness of 40 nm. The CBP is used as a host and Ir(ppy)₂(acac) is used as a phosphorescent guest (the doping ratio of the guest is 8 wt % and the thickness of the guest is 15 nm) to form the light-emitting layer. TmPyPB is used as an electron transport layer, with a thickness of 45 nm. Liq is used as an electron injection layer, with a thickness of 1 nm. The used cathode is Al (100 nm).

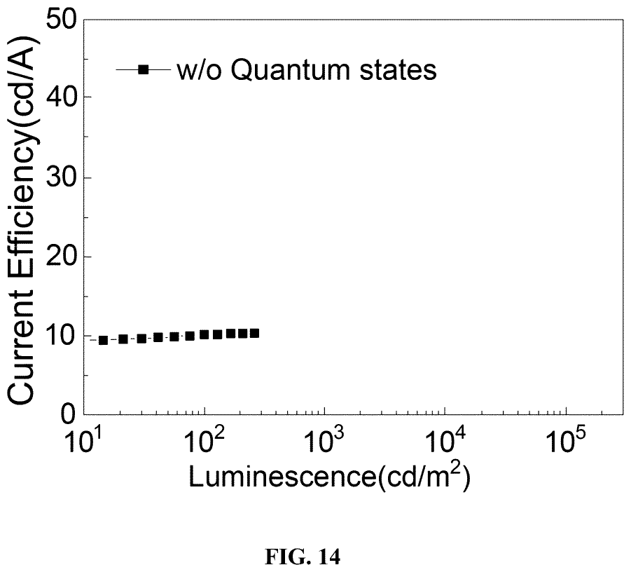

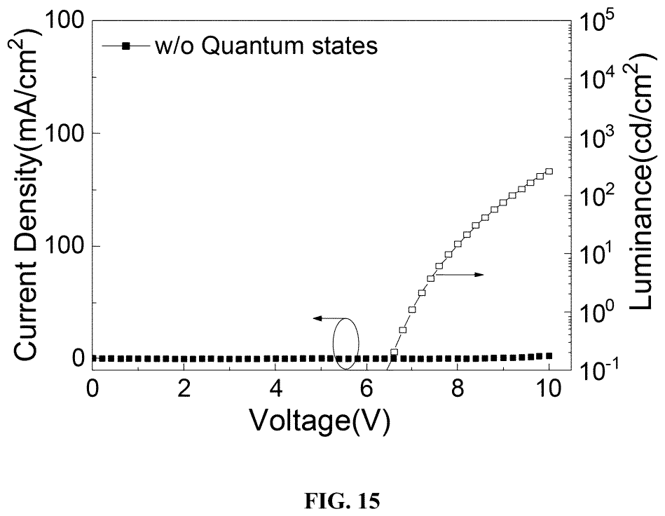

FIG. 14 shows a current density-luminance-voltage (J-L-V) curve of a top-emitting OLED device when an anode without quantum state generation is used. The abscissa is luminescence, the ordinate is current efficiency. FIG. 15 is a curve showing the current efficiency and power efficiency of a top-emitting device. The abscissa is voltage, the (left) ordinate is current efficiency, and the (right) ordinate is luminance. It can be found that for the ITO/HAT-CN anode without quantum state in a surface, a turn-on voltage of the top-emitting OLED device is within 6.6 V, and the device is poor. This embodiment once again proves the necessity of the quantized anode for achieving effective hole injection and high-performance devices.

Various embodiments in this specification are described in a progressive way, and each embodiment focuses on the differences from other embodiments, so it is only necessary to refer to the same and similar parts between the embodiments. In addition, a person of ordinary skill in the art can make changes in terms of specific embodiments and scope of application in accordance with the teachings of the present disclosure. In conclusion, the content of this specification shall not be construed as a limitation to the present disclosure.

What is claimed is:

1. An anode with surface quantum states, comprising:
a substrate, a conductive anode, and a surface quantum state generation region, which are arranged in sequence from bottom to top.

2. The anode with surface quantum states according to claim 1, wherein the substrate is a silicon with integrated transistors, or a substrate comprising thin film transistors.

3. The anode with surface quantum states according to claim 1, wherein the conductive anode comprises metal, or a metal alloy.

4. The anode with surface quantum states according to claim 1, wherein the conductive anode comprises aluminum.

5. The anode with surface quantum states according to claim 3, wherein the conductive anode comprises one of copper, nickel, platinum, an aluminum-copper alloy, or an aluminum-titanium alloy.

6. The anode with surface quantum states according to claim 4, wherein the surface quantum state generation region comprises metal and an organic compound; and
the metal and the organic compound in the surface quantum state generation region are capable of undergoing a charge transfer reaction.

7. The anode with surface quantum states according to claim 6, wherein the organic compound is an organic compound with a lowest unoccupied molecular orbital level comparable to the work function of the metal and capable of accepting charges from the metal.

8. The anode with surface quantum states according to claim 6, wherein the organic compound is HAT-CN (Dipyrazino[2,3-f:2′,3′-h]quinoxaline-2,3,6,7,10,11-hexacarbonitrile).

9. A semiconductor device, comprising:
an anode layer, a hole transport layer, an electroluminescent layer, an electron transport layer, an electron injection layer and a conductive cathode layer, which are arranged in sequence from top to bottom; and
wherein the anode layer is the anode with surface quantum states according to claim 1.

10. The semiconductor device according to claim 9, wherein material of the hole transport layer is one of CBP (4, 4′-N, N′-dicarbazole-biphenyl), TCTA (4,4′,4″-tris(carbazol-9-yl)triphenylamine), TAPC (4,4′-cyclohexylidenebis[N,N-bis(p-tolyl)aniline]), NPB (N, N′-diphenyl-N, N′-bis(1-naphthyl-phenyl)-1, 1′-biphenyl-4, 4′-diamine), or m-MTDATA (4,4′,4″-Tris(N-3-methylphenyl-N-phenylamino)triphenylamine).

11. The semiconductor device according to claim 9, wherein material of the electroluminescent layer is one of Ir(ppy)₂(acac) (Bis(2-phenylpyridinato-C2,N) (acetylacetonate) iridium (III)), Ir(MDQ)₂(acac) (Bis(2-methyldibenzo[f,h]quinoxaline) (acetylacetonate) iridium (III)), Firpic (Bis[2-(4, 6-difluorophenyl)pyridinato-C2,N](picolinato) iridium (III)), quantum dots, or perovskite.

12. The semiconductor device according to claim 9, wherein the conductive cathode layer is made of transparent and conductive materials.

13. The semiconductor device according to claim 9, wherein the substrate is a silicon with a driving circuit, or a substrate comprising thin film transistors.

14. The semiconductor device according to claim 9, wherein the conductive anode comprises metal, or a metal alloy.

15. The semiconductor device according to claim 9, wherein the conductive anode comprises aluminum.

16. The semiconductor device according to claim 14, wherein the conductive anode comprises one of copper, nickel, platinum, an aluminum-copper alloy, or an aluminum-titanium alloy.

17. The semiconductor device according to claim 9, wherein the surface quantum state generation region comprises metal and an organic compound; and
the metal and the organic compound in the surface quantum state generation region are capable of undergoing a charge transfer reaction.

18. The semiconductor device according to claim 17, wherein the organic compound is an organic compound with a lowest unoccupied molecular orbital level comparable to the work function of the metal and capable of accepting charges from the metal.

19. The semiconductor device according to claim 17, wherein the organic compound is HAT-CN (Dipyrazino[2,3-f:2′,3′-h]quinoxaline-2,3,6,7,10,11-hexacarbonitrile).

20. The semiconductor device according to claim 12, wherein the anode layer and the conductive cathode layer are connected to a power supply.
